(19) United States
(12) Patent Application Publication
(10) Pub. No.: US 2003/0016555 A1
(43) Pub. Date: Jan. 23, 2003

(54) Semiconductor integrated circuit device

(75) Inventors: Noriaki Kubota, Higashiyamato (JP); Takeshi Hashimoto, Hachioji (JP)

Correspondence Address: MILES & STOCKBRIDGE PC, 1751 PINNACLE DRIVE, SUITE 500, MCLEAN, VA, 22102-3833, US

(73) Assignee: Hitachi, Ltd.

(21) Appl. No.: 10/183,345

(22) Filed: Jun. 28, 2002

(30) Foreign Application Priority Data
Jul. 23, 2001 (JP) 2001-221931

(51) Int. Cl. G11C 11/34

(52) U.S. Cl. 365/177

(57) ABSTRACT

Reading of memory configured with PLED transistors is sped up. In a direction orthogonal to source power lines GND of MISFET Tr1, shunt lines SL grounded at both ends thereof and electrically connected with the source power lines GND are inserted to expel noise (potential) developing in the source power lines GND to ground potential. By expelling noise (potential) developing in the source power lines GND to ground potential, a decrease in a source-to-drain voltage of MISFET Tr1 is suppressed.

### BACKGROUND OF THE INVENTION

The present invention relates to a semiconductor integrated circuit device, and more particularly to technology effectively applied to a semiconductor integrated circuit device having PLED (Phase-state Low Electron-number Drive) transistors.

In a DRAM (Dynamic Random Access Memory) used as a main memory of an electronic computer, a memory cell for storing information comprises one capacitor and a transistor for reading information charge stored in the capacitor. Therefore, the DRAM is suited for large scale integration because it can be configured with a minimum of components as a RAM (Random Access Memory).

However, in the DRAM, since the memory cell itself has no amplification function, a read signal voltage from the memory cells becomes small and the operation of the memory cells becomes susceptible to influence of various types of noises. Moreover, information charge stored in the capacitor is lost because of a pn junction current (leak current) existing in the memory cell. In short, the DRAM is prone to become unstable in operation. Accordingly, the information is retained by periodically subjecting the memory cell to a refresh operation (rewrite) before the information charge is lost. The cycle (referred to as refresh time) must be made longer as the storage capacity of the DRAM increases.

By the way, there is an attempt to increase the scale of integration of a DRAM by making elements constituting the DRAM microscopic. However, as described above, since refresh time becomes longer as the storage capacity of the DRAM increases, it is becoming difficult to achieve the miniaturization of elements constituting the DRAM and the stability of DRAM operation at the same.

On the other hand, in contrast to the DRAM which is volatile memory, there is nonvolatile EEPROM (Electric Erasable Programmable Read Only Memory; hereinafter referred to as flash memory). Since the flash memory has gains within memory cells, a read signal voltage from the memory cells is magnified. In short, the operation of the memory cells is stable. Also, since information charges are stored in storage nodes surrounded by insulating films, no pn junction current occurs as in DRAM, so that a refresh operation is unnecessary.

However, since the flash memory stores charges by supplying weak tunnel currents through storage nodes, it takes a long time to write to the flash memory. Also, since repeated writes to the memory cells forcibly feed currents to insulating films surrounding the storage nodes, the insulating films deteriorate gradually and ultimately become conductive films, losing the storage holding capability.

The inventor et al. study memory (hereinafter referred to as PLED memory) configured with PLED transistors to solve the problems of the DRAM and flash memory.

The PLED transistor has such a structure that three thin tunnel insulating films are inserted in a channel portion and controls the flow of electrons by changing the height of the tunnel barrier by an external voltage. In the PLED memory, PLED transistors having gains are substituted for capacitors in DRAM and two transistors are stereoscopically integrated. As a result, the size of a memory cell can be reduced to almost half the size of a DRAM memory cell; for an identical size, the storage capacity can be increased about twice.

In the PLED memory, since memory cells have gains, the number of electrons stored for each cell can be brought to about a hundredth that of a DRAM cell. Since the PLED transistor having a tunnel structure structurally embraces electrons, loads on DRAM by refresh operation are reduced. That is, in the PLED memory, elements constituting the PLED memory can be made microscopic, and at the same time the operation of the PLED memory can be stabilized.

Furthermore, the PLED memory is almost identical with DRAM in read time and write time. By forming memory cells structured so that no pn junction current exists, the memory cells can be made to function as nonvolatile memory. In short, different uses between fast and volatile DRAM and slow and nonvolatile flash memory for different purposes can be eliminated.

Technology of PLED transistors included in the PLED memory is disclosed in Japanese Published Unexamined Patent Application No. Hei 10(1998)-200001 and 2000-113683 and the like.

### SUMMARY OF THE INVENTION

By the way, the inventor et al. found out the following problems in the PLED memory.

That is, as shown in FIG. 1, in a memory cell of the PLED memory, a PLED transistor PLED is electrically connected with a write bit line BLW, a word line WLW for selecting write memory cells, and MISFET (Metal Insulator Semiconductor Field Effect Transistor) Tr1. A source power line GND of MISFET Tr1 is disposed in parallel to word lines (a word line WLR for selecting read memory cells and the word line WLW for selecting write memory cells) and vertically to bit lines (the read bit line BLR and the write bit line BLW). FIG. 2 shows a circuit diagram of a memory array configured with the memory cell shown in FIG. 1.

As the source power line GND, e.g., a semiconductor area formed on a semiconductor substrate is used and its sheet resistance is 80 about 80 Ω/□. As the above described memory array, when a subarray of 512 by 256 word bits is took up as an example, if word line length and width are 256 μm and 0.18 μm, respectively, a resistance value of the source power line GND is as high as about 56 kΩ at almost the center of the word line.

In the case where ‘1’ data is written to all memory cells on a selected word line WLR, if the ‘1’ data is read, MISFET Tr1 and Tr2 go on and current I flows from a read bit line BLR to a source power line GND. At this time, since currents from all the selected memory cells flow into the source power line GND, potential of the source power line GND develop as noise. The noise is maximum at a point farthest from ground potential, that is, near the center of the source power line GND. As a result, the vicinity of the central bit B1 of the selected word line WLR is most strongly influenced by the noise. In other words, a difference between a read speed of the central bit B1 and that at a bit B2 near to a word driver WD becomes the largest.

The operation of sense amplifiers of the memory array must be timed to coincide with a read operation of the central bit B1 at which a read speed becomes the lowest. That is, since a read speed of the memory array greatly depends on a read speed of the central bit B1, there is a problem in that it is difficult to increase the read speed.

An object of the present invention is to provide technology for increasing a read operation of the PLED memory.

The above and other objects, and novel characteristics of the present invention will become apparent from the specifications and the accompanying drawings.

Of inventions disclosed by the present patent application, typical ones are briefly described below.

The present invention has a memory array which comprises memory cells each including a first transistor and a second transistor having a first electrode, a second electrode, and a third electrode, and includes a first area and a second area, wherein the first electrode of the first transistor is electrically connected with a second wiring; the second electrode of the first transistor is electrically connected with a first wiring; the third electrode of the first transistor is electrically connected with the first electrode of the second transistor; the second electrode of the second transistor is electrically connected with a third wiring connected to power potential at ends thereof; in the first area, the third electrode of the second transistor is electrically connected with a fourth wiring; in the second area, the third electrode of the second transistor is electrically connected with a seventh wiring connected to power potential; in the second area, the seventh wiring is electrically connected with the third wiring; and the second area is disposed at a predetermined interval in the memory array.

The present invention has a memory array which comprises memory cells each including a first transistor, a second transistor, and a third transistor having a first electrode, a second electrode, and a third electrode, and includes a first area and a second area, wherein the first electrode of the first transistor is electrically connected with a second wiring; the second electrode of the first transistor is electrically connected with a first wiring; the third electrode of the first transistor is electrically connected with the first electrode of the second transistor; the second electrode of the second transistor is electrically connected with a third wiring connected to power potential at ends thereof; in the first area, the third electrode of the second transistor is electrically connected with a fourth wiring through the third transistor; in the second area, the third electrode of the second transistor is electrically connected with a seventh wiring connected to power potential through the third transistor; in the second area, the seventh wiring is electrically connected with the third wiring; and the second area is disposed at a predetermined interval in the memory array.

The present invention has a memory array which comprises memory cells each including a first transistor, a second transistor, and a third transistor having a first electrode, a second electrode, and a third electrode, wherein the first electrode of the first transistor is electrically connected with a second wiring; the second electrode of the first transistor is electrically connected with a fifth wiring; the third electrode of the first transistor is electrically connected with a first electrode of the second transistor; the second electrode of the second transistor is electrically connected with a third wiring connected to power potential at ends thereof; the third electrode of the second transistor is electrically connected with a fifth wiring through the third transistor; and the third wiring is electrically connected with a seventh wiring connected to power potential.

The present invention has a memory array which comprises memory cells each including a first transistor and a second transistor having a first electrode, a second electrode, and a third electrode, and a capacitor, and includes a first area and a second area, wherein the first electrode of the first transistor is electrically connected with a sixth wiring; the second electrode of the first transistor is electrically connected with a first wiring; the third electrode of the first transistor is electrically connected with the first electrode of the second transistor and the capacitor; the second electrode of the second transistor is electrically connected with a third wiring connected to power potential at ends thereof; in the first area, the third electrode of the second transistor is electrically connected with a fourth wiring; in the second area, the third electrode of the second transistor is electrically connected with a seventh wiring connected to power potential; in the second area, the seventh wiring is electrically connected with the third wiring; the second area is disposed at a predetermined interval in the memory array; and the capacitor is electrically connected with the sixth wiring.

The present invention has a memory array which comprises plural memory cells each including a transistor electrically connected to power potential and includes a first area and a second area, wherein the adjacent memory cells are electrically connected to power potential by a third wiring; memory cells in the first area are electrically connected to a fourth wiring; memory cells in the second area are electrically connected with a seventh wiring formed by the same conductive layer as the fourth wiring; and the seventh wiring is electrically connected with the third wiring.

### BRIEF DESCRIPTION OF THE DRAWINGS

FIG. 1 is a schematic circuit diagram of a memory cell of conventional PLED memory studied by the inventor et al.;

FIG. 2 is a schematic circuit diagram of a memory array of the conventional PLED memory studied by the inventor et al.;

FIG. 3 is a schematic circuit diagram of a memory array of PLED memory of one embodiment of the present invention;

FIG. 4 is a plan view of a main portion of a PLED memory with which the PLED memory of one embodiment of the present invention is compared for study by the inventor et al.;

FIG. 5 is a plan view of a main portion of a PLED memory with which the PLED memory of one embodiment of the present invention is compared for study by the inventor et al.;

FIG. 6 is a plan view of a main portion of the PLED memory of one embodiment of the present invention;

FIG. 7 is a diagram for explaining a disposition method of shunt lines in the PLED memory of one embodiment of the present invention;

FIG. 8 is a sectional view of a main portion of the PLED memory of-one embodiment of the present invention;

FIG. 9 is a sectional view of a main portion of the PLED memory of one embodiment of the present invention;

FIG. 10 is a sectional view of a main portion of the PLED memory of one embodiment of the present invention;

FIG. 11 is a diagram for explaining a relationship between disposition intervals of shunt lines in the PLED memory of one embodiment of the present invention, and the read speeds of a central bit between shunt lines and a bit near to a shunt line;

FIG. 12 is an operation voltage waveform diagram showing operation voltage waveforms of a read bit line, a word line for selecting read memory cells, and a word line for selecting write memory cells in PLED memory with which the PLED memory of one embodiment of the present invention is compared for study by the inventor et al.;

FIG. 13 is an operation voltage waveform diagram showing operation voltage waveforms of a read bit line, a word line for selecting read memory cells, and a word line for selecting write memory cells in the PLED memory of one embodiment of the present invention;

FIG. 14 is a schematic circuit diagram of a PLED memory cell of another embodiment of the present invention;

FIG. 15 is a schematic circuit diagram of a memory array of PLED memory, configured with the memory cell shown in FIG. 14;

FIG. 16 is a schematic circuit diagram of a PLED memory cell of another embodiment of the present invention;

FIG. 17 is a schematic circuit diagram of a memory array of PLED memory, configured with the memory cell shown in FIG. 16; and

FIG. 18 is a plan view of a main portion showing a plane layout of the memory array shown in FIG. 17.

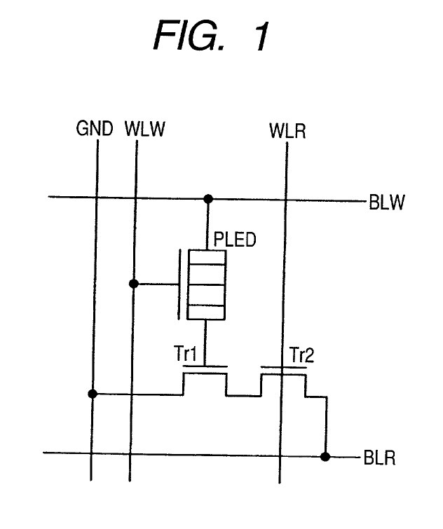

### DETAILED DESCRIPTION OF THE PREFERRED EMBODIMENTS

Hereinafter, embodiments of the present invention will be described in detail with reference to the accompanying drawings. In all drawings for explaining the embodiments, members having the same functions are identified by the same reference numerals and are not described duplicately. Plan views may be hatched for convenience of description.

(First Embodiment)

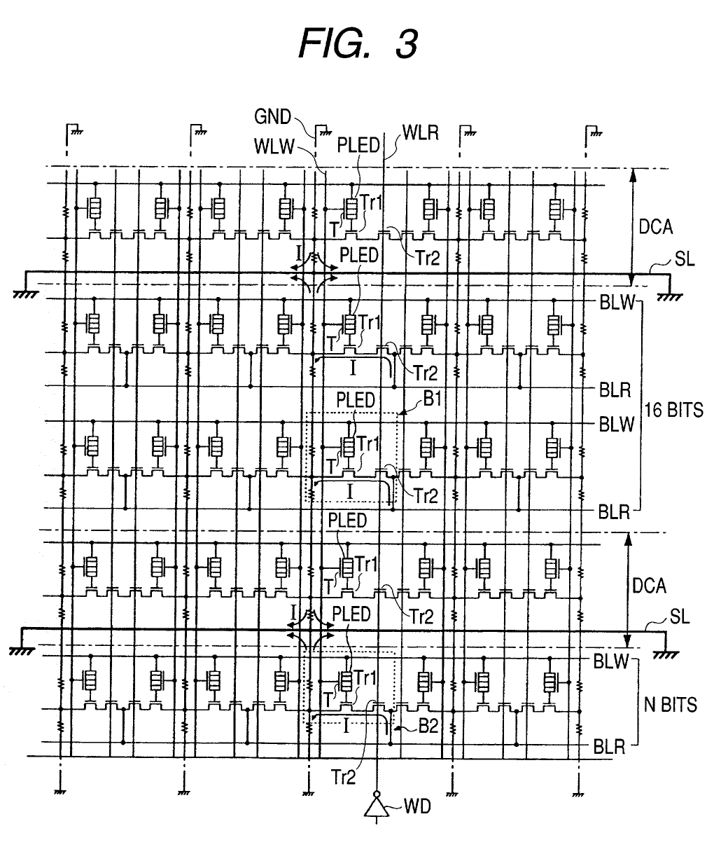

FIG. 3 is a circuit diagram of a memory array of PLED memory (semiconductor integrated circuit device) of a first embodiment.

As shown in FIG. 3, the memory array of the first embodiment is provided with PLED transistors (first transistors) PLED each having three electrodes, first, second, and third electrodes wherein the second electrode is electrically connected with a write bit line (first wiring) BLW, the first electrode is electrically connected with a word line (second wiring) WLW for selecting a write memory cell, and the third electrode is electrically connected with a gate (first electrode) of MISFET (second transistor) Tr1. Source power lines (third wiring) GND electrically connected with a source (second electrode) of MISFET Tr1 are disposed in parallel with word lines (word lines WLR for selecting a read memory cell and word lines WLW for selecting a write memory cell) and vertically to bit lines (read bit lines (fourth wiring) BLR and write bit lines BLW) The read bit lines BLR are electrically connected with a drain (third electrode) of MISFET Tr1 via MISFET (third transistor) Tr2.

Shunt lines SL (seventh wiring) are inserted in a direction orthogonal to source power lines GND of MISFET Tr1. The shunt lines SL are electrically connected with the source power lines GND and grounded at both ends thereof. The source power lines GND are also grounded at both ends thereof. Providing the shunt lines SLs in this way makes it possible to expel noise (potential) developing in the source power lines GND to the ground potential. Also, since a decrease in a source-to-drain voltage of MISFET Tr1 due to the noise developing in the source power lines GND can be suppressed, deterioration in a source-to-drain current of MISFET Tr1 can also be suppressed. As a result, a difference between a read speed of a central bit B1 of the word lines WLR and a read speed of a bit B2 near to the word driver WD can be reduced. This will be described in detail later.

In the memory array of the first embodiment, word lines (word lines WLR and WLW) and bit lines (read bit lines BLR and write bit lines BLW) are disposed with a minimum work size and positioned above the source power lines GND. The source power lines GND comprise semiconductor areas formed on a semiconductor substrate.

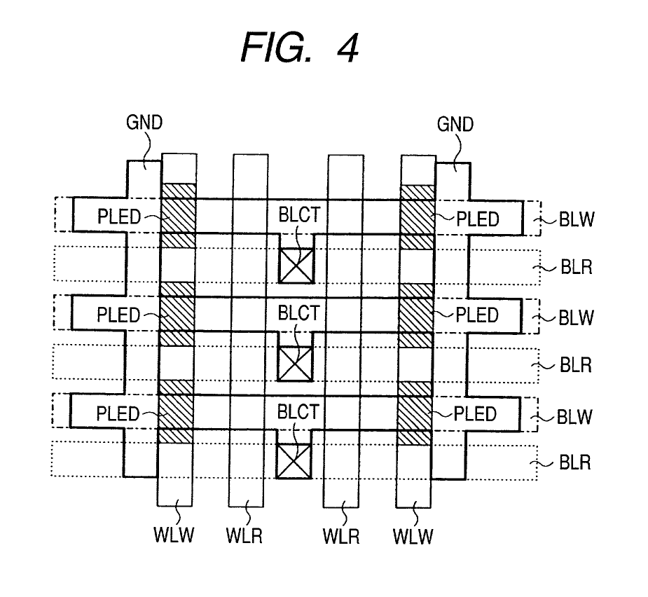

FIG. 4 is a plan layout diagram of a memory array with which the memory array of the first embodiment is compared for study by the inventor et al. The source power lines GND are electrically connected with read bit lines BLR via plugs formed within contact holes BLCT. Hatched areas are areas in which a PLED transistor PLED is formed. Also in the memory array shown in FIG. 4, word lines and bit lines are disposed with a minimum work size and positioned above the source power lines GND. The source power lines GND comprise semiconductor areas formed on a semiconductor substrate.

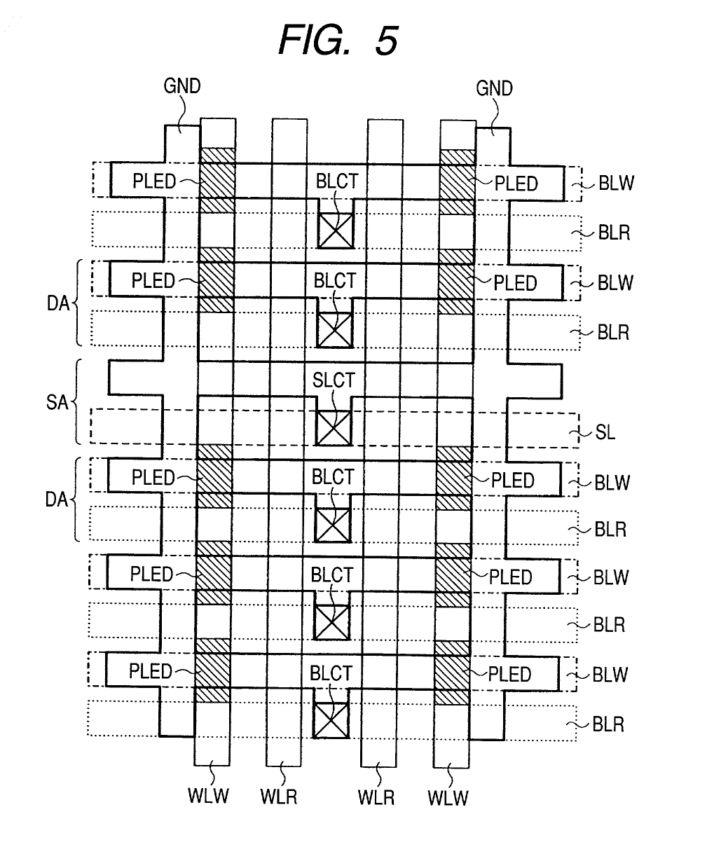

In the case of the layout shown in FIG. 4, since the word lines and bit lines are disposed with a minimum work size as described above and positioned above the source power lines GND, it is difficult to provide shunt lines SL to electrically connect the shunt lines SL with only the source power lines GND. Accordingly, as a conceivable method, as shown in FIG. 5, an area SA for disposing a shunt line SL is provided to electrically connect the shunt line SL and the source power lines GND via plugs formed within the contact holes SLCT. However, providing the area SA would collapse the regularity of memory cell disposition in the area SA. For this reason, if memory cells are formed using high resolution exposure technology such as the phase shift method, memory cells formed in areas DA at both ends of the area SA may be deformed. In short, the memory cells formed within the areas DA must be treated as dummy cells actually not used as memory cells. As a result, if a memory array of a desired storage capacity is to be formed, the memory array would increase in area and a semiconductor chip having the memory array would increase in area.

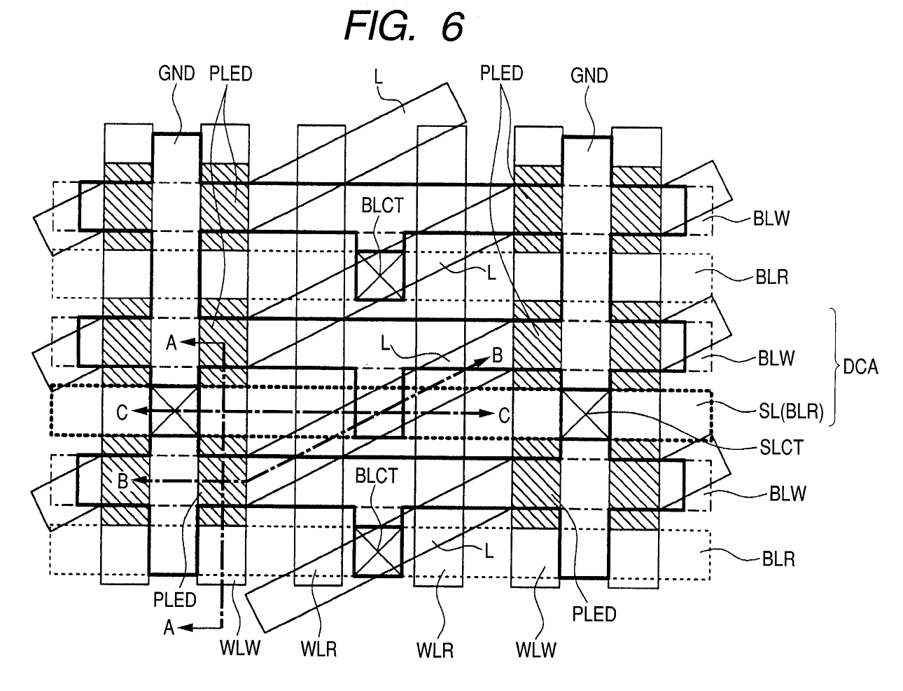

To prevent the area increase, in the PLED memory of the first embodiment, as shown in FIG. 6, memory cells of one bit in areas DCA (second areas (see FIG. 3)) are regarded as dummy cells and are made to function as memory cells in other areas (first areas). In short, bit lines BLR for reading the dummy cells are used as the shunt lines SL. Since this eliminates the need to provide the areas SA for disposing the shunt lines SL, the regularity of memory cell disposition can be maintained. Also, the areas SA can be omitted, the areas DA at both ends of the areas SA do not need to be considered, and memory cells treated as dummy cells are no more than one bit. In other words, the memory array of the first embodiment can be prevented from increasing in area, in comparison with the memory array shown in FIG. 5.

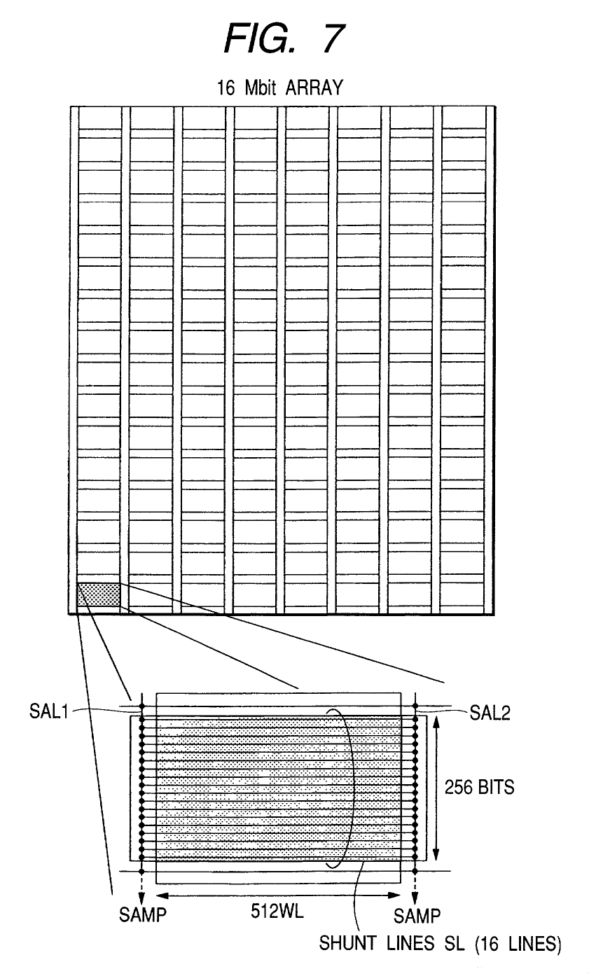

FIG. 7 is a diagram for explaining the number of lines the shunt lines SL are disposed.

As shown in FIG. 7, in the first embodiment, a 16-Mbit memory array is formed by subarrays of 512 by 256 word bits each. In the first embodiment, e.g., 16 shunt lines SL are disposed in one subarray. In short, one shunt line SL is disposed every 16 bits. Both ends of each shunt line SL are connected to wirings SAL1 and SAL2 electrically connected with sense amplifiers SAMP.

The inventor et al. experienced area increase ratios of the memory array (see FIG. 5) in which areas SA for disposing shunt lines SL are provided and shunt lines SL are disposed, and the memory array (see FIG. 6) of the first embodiment to the memory array (see FIG. 4) not using shunt lines SL. One shunt line SL is disposed every 16 bits (see FIG. 7). As a result, an area increase ratio of the memory array shown in FIG. 5 was about 18%, while an area increase ratio of the memory array of the first embodiment was about 6%. That is, it was proven from the experiment result that the memory array of the first embodiment could be prevented from increasing in area, in comparison with the memory array shown in FIG. 5.

Moreover, since the bit lines BLR for reading dummy cells are used as the shunt lines SL, the contact holes SLCT for electrically connecting the shunt lines SL and the source power lines GND can be easily holed.

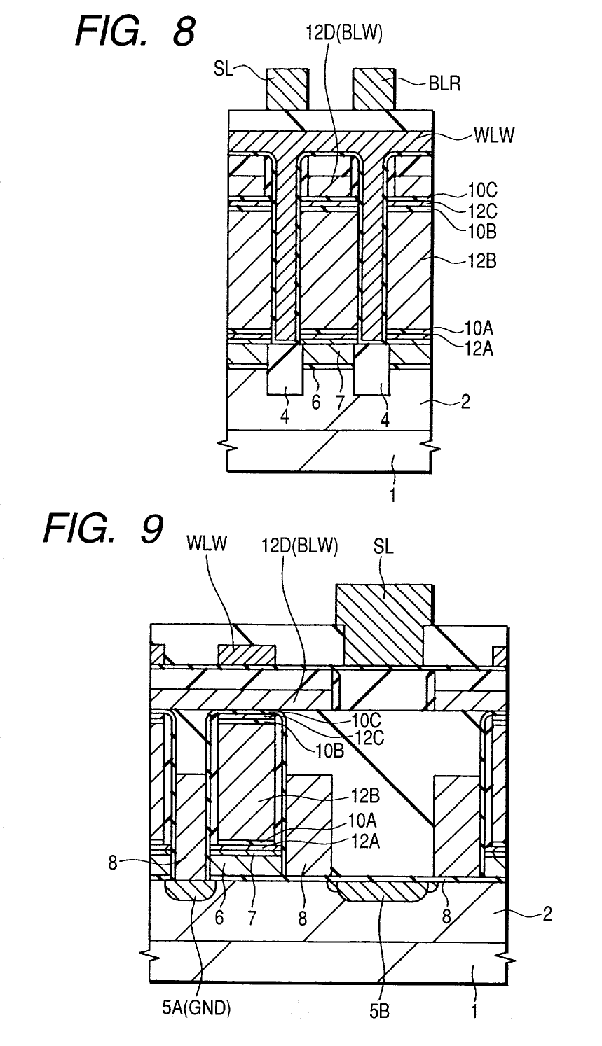

FIGS. 8 to 10 are sectional views corresponding to lines A-A, B-B, and C-C of FIG. 6, respectively.

Element separating grooves 4 are formed in a p-type well 2 formed on a main surface (element formation surface) of the semiconductor substrate 1. Plural memory cells are formed in active areas L (see FIG. 6) of the p-type well 2 whose periphery is defined by the element separating grooves.

In the p-type well 2 are formed n-type (first conduction type) semiconductor areas 5A (first semiconductor area) and 5B formed by implanting e.g., As (arsenic) or P (phosphorus) by ion implantation. Polycrystalline silicon films 6 and 7 serve as a gate and drain of MISFET Tr1, respectively, and form the MISFET Tr1 in conjunction with the n-type semiconductor area 5A, which serves as a source thereof. On the other hand, a polycrystalline silicon film 8 serves as a gate of MISFET Tr2 and forms the MISFET Tr2 in conjunction with the polycrystalline silicon film 7, which serves as a drain thereof, and the n-type semiconductor areas 5B, which serves as a source thereof. The n-type semiconductor area 5A can function as the source power line GND with a sheet resistance of about 80 Ω/□.

The PLED transistor PLED (see FIG. 3) is formed in such a form that three tunnel insulating films 10A, 10B, and 10C are sandwiched by polycrystalline silicon films 12A, 12B, 12C, and 12D. The polycrystalline silicon film 12D can function as a write bit line BLW.

The read bit line BLR (shunt line SL) can be formed of e.g., an Al (aluminum) film or W (tungsten) film, with a wiring width of about 0.2 μm and a sheet resistance of about 4.5 Ω/□. The Al or W film is embedded within the contact hole SLCT and forms a plug. The plug is electrically connected with the source power line GND (n-type semiconductor area 5A) via the polycrystalline silicon film.

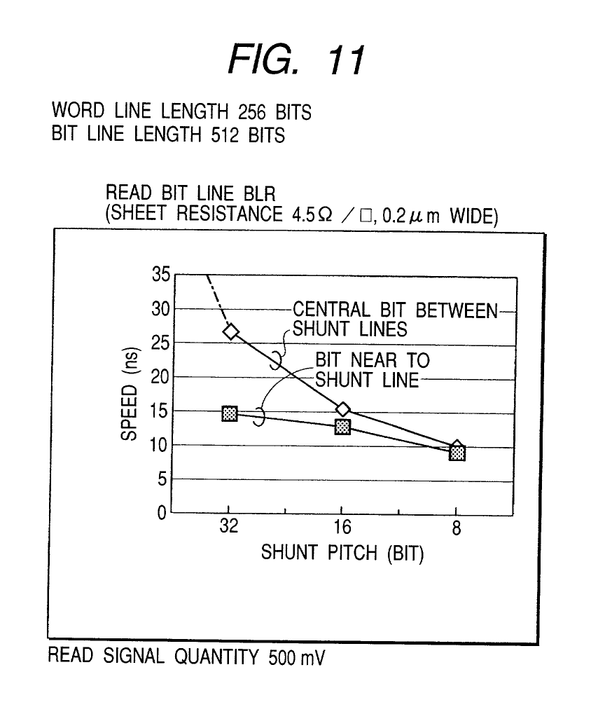

FIG. 11 is a diagram for explaining a relationship between disposition intervals (number of lines) of shunt lines SL, and the read speeds of a central bit between shunt lines and a bit near to a shunt line. The relationship was obtained as a result of experiments on the subarray (see FIG. 7) of the first embodiment by the inventors. A read signal quantity is about 500 mV.

As shown in FIG. 11, it is understood that, as a disposition interval of shunt lines SL becomes smaller, the difference between the read speed of a central bit between shunt lines SL and the read speed of a bit near to a shunt line becomes smaller. It is understood from FIG. 11 that, in the first embodiment, a disposition interval of shunt lines SL is 16 bits and, in the case, the difference between the read speed of a central bit between shunt lines SL and the read speed of a bit near to a shunt line is about 2 ns (nanoseconds).

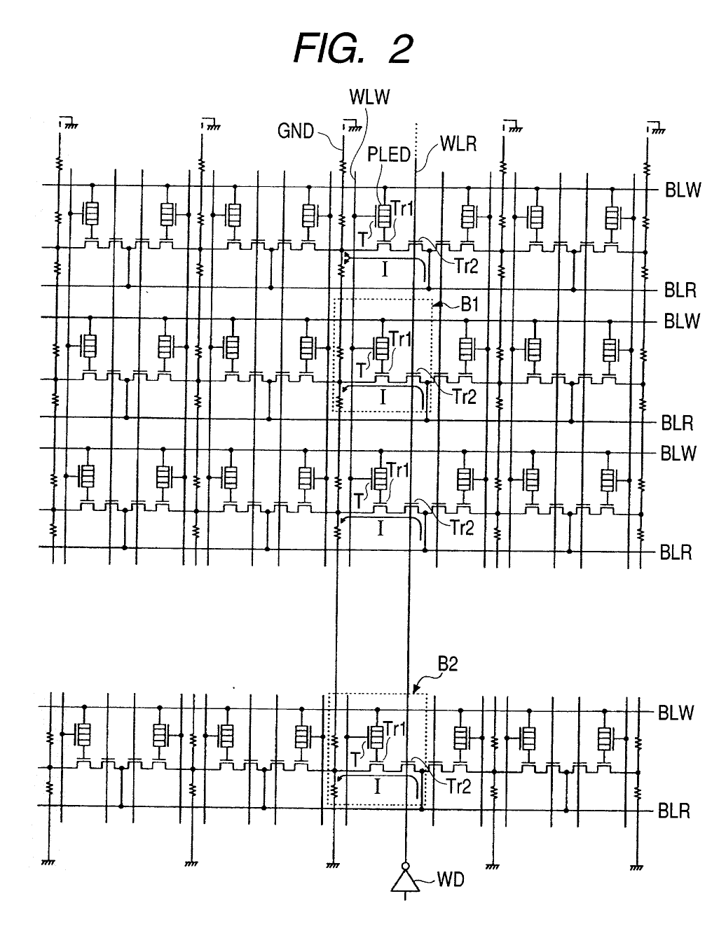

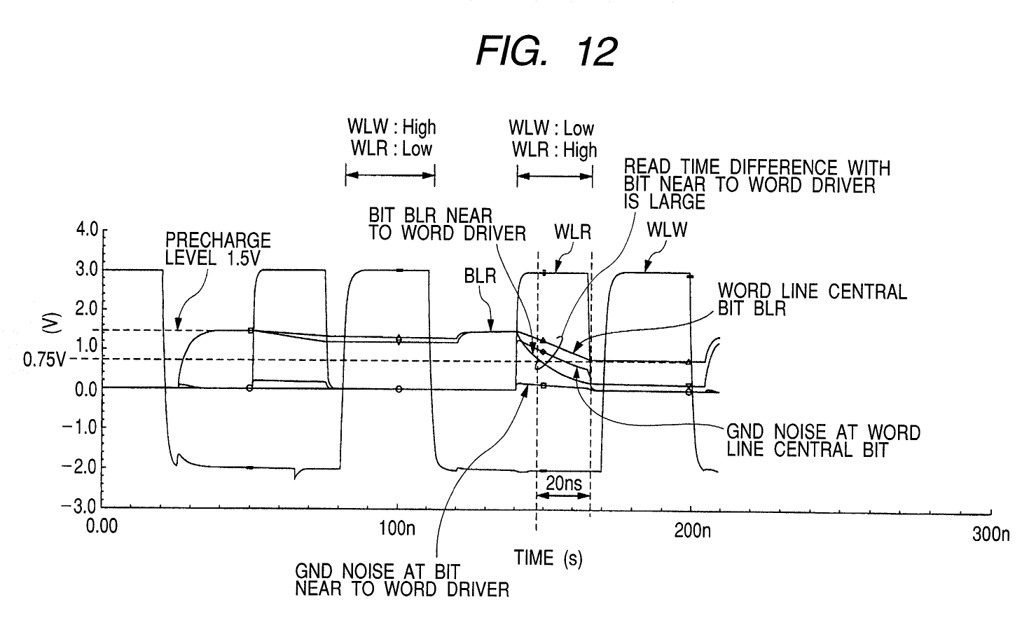

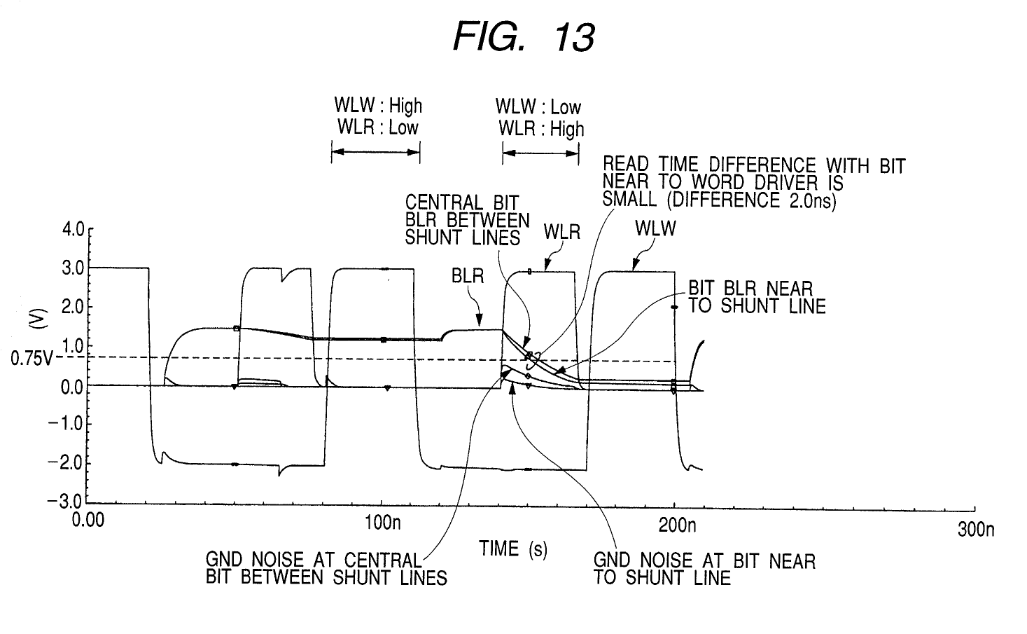

FIG. 12 shows operation voltage waveforms of a read bit line BLR, a word line WLR, and a word line WLW in the memory array (see FIG. 2) in which the shunt lines SL are not provided. FIG. 13 shows operation voltage waveforms of a read bit line BLR, a word line WLR, and a word line WLW in the memory array of the first embodiment. FIGS. 12 and 13 both show operation voltage waveforms in the case where “1” is written to a memory cell by driving a word line WLW High and a word line WLR Low, and then “1” is read into a read bit line BLR by driving the word line WLW Low and the word line WLR High.

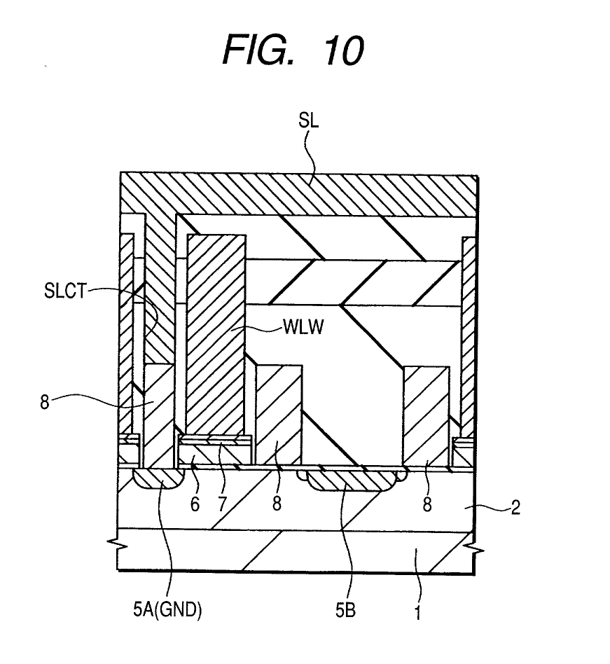

In the memory array in which the shunt lines SL are not provided, the length of a source power line GND is about 256 μm. In this case, as described above, since the sheet resistance of the n-type semiconductor area 5A (see FIGS. 9 and 10), which serves as the source power line GND, is about 80 Ω/□, the resistance value of the source power line GND corresponding to a length from the word driver WD (see FIG. 2) to the central bit B1 (see FIG. 2) is about 56 kΩ. A read signal quantity is set to the half (0.75 V) of the precharge level (1.5 V). In this situation, the potential of the source power line GND develops as noise, requiring the longest time to read the central bit of the word line WLR (see FIG. 2). As shown in FIG. 12, a read time of the central bit B1 is about 20 ns slower than a read time of the bit B2 (see FIG. 2) near to the word driver WD.

On the other hand, in the memory array of the first embodiment, since the provided shunt lines SL enable the potential of the source power line GND to be expelled to a ground potential, the noise can be reduced. That is, a delay of a read time of the central bit B1 of the word line WLR can be reduced. As shown in FIG. 13, in the memory array of the first embodiment, a read time of the central bit B1 can be improved to no more than about 2 ns slower than a read time of the bit B2 (see FIG. 3) near to the word driver WD (see FIG. 3). As a result, since the operation timing of sense amplifiers of the memory array of the first embodiment can be sped up, a read speed of the memory array of the first embodiment can be increased.

(Second Embodiment)

In a second embodiment, the present invention is applied to a memory array of another PLED memory.

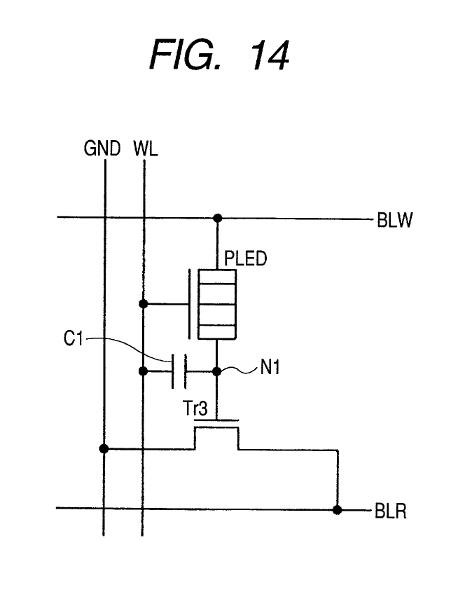

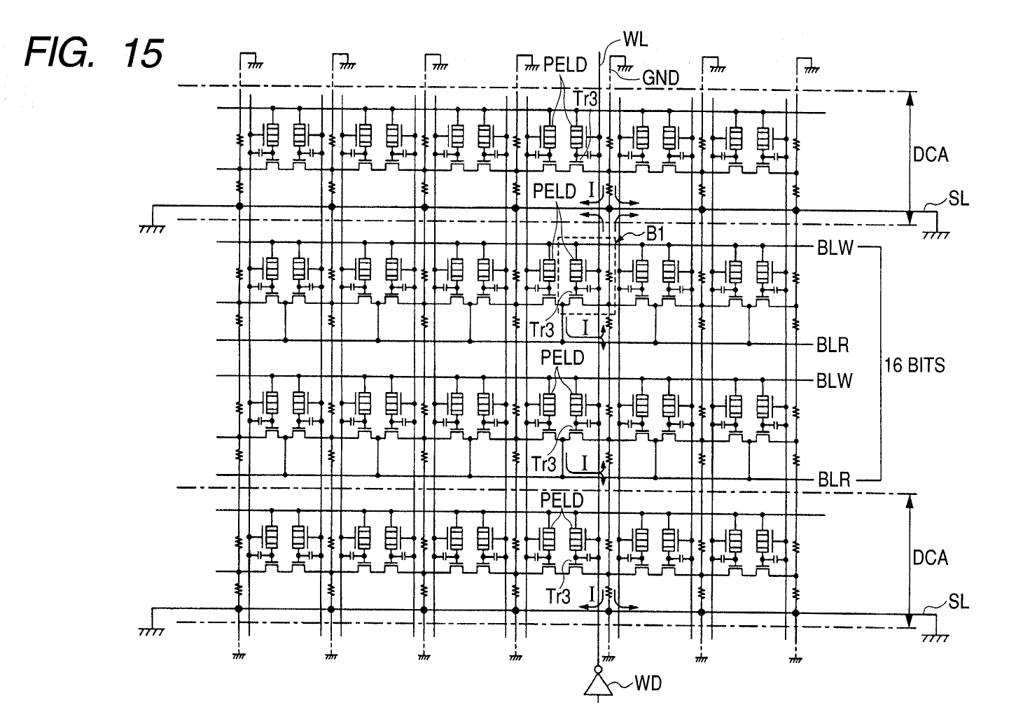

FIG. 14 is a schematic circuit diagram of a memory cell of the second embodiment. FIG. 15 is a schematic circuit diagram of a memory array using the memory cell shown in FIG. 14.

In the second embodiment, the MISFET Tr1 and Tr2 (see FIG. 3) used in the first embodiment are not provided, and MISFET (second transistor) Tr3 is provided of which a source is electrically connected with a source power line GND, a drain is electrically connected with a read bit line BLR, and a gate is electrically connected with a third electrode of a PLED transistor PLED. A information storage node N1 exists between the PLED transistor PLED and the gate of MISFET Tr3, and a capacitor C1 is electrically connected between the information storage node N1 and the word line (sixth wiring) WL.

Also in the memory array of the second embodiment as described above, like the memory array (see FIG. 3) of the first embodiment, memory cells of one bit in areas DCA (see FIG. 3) are regarded as dummy cells and are made to function as memory cells in other areas (first areas). In short, bit lines BLR for reading the dummy cells can be used as the shunt lines SL. Since this eliminates the need to provide the areas SA (see FIG. 5) for disposing the shunt lines SL also in the memory array of the second embodiment, the regularity of memory cell disposition can be maintained. Also, the areas SA can be omitted, the areas DA (see FIG. 5) at both ends of the areas SA do not need to be considered, and memory cells treated as dummy cells are no more than one bit. In other words, the memory array of the second embodiment can be prevented from increasing in area, in comparison with the memory array for which the area SA is provided. In the second embodiment, like the first embodiment, in a subarray of, e.g., 512 by 256 word bits, one shunt line SL is disposed every 16 bits.

In the memory array of the second embodiment as described above, since the provided shunt lines SL enable the potential of the source power line GND to be expelled to a ground potential, noise from the source power line GND can be reduced. Since a decrease in a source-to-drain voltage of MISFET Tr1 due to the noise developing in the source power lines GND can be suppressed, deterioration in a source-to-drain current of MISFET Tr1 can also be suppressed. That is, since a delay of a read time of the central bit B1 (see FIG. 15) of the word line WLR can be reduced, a difference between a read speed of the central bit B1 of the word line WLR and a read speed of a bit near to the word driver WD can be reduced. As a result, since the operation timing of sense amplifiers of the memory array of the second embodiment can be sped up, a read speed of the memory array of the second embodiment can be increased.

(Third Embodiment)

In a third embodiment, the write bit lines and read bit lines in the memory array (see FIGS. 3 and 6) of the first embodiment are shared.

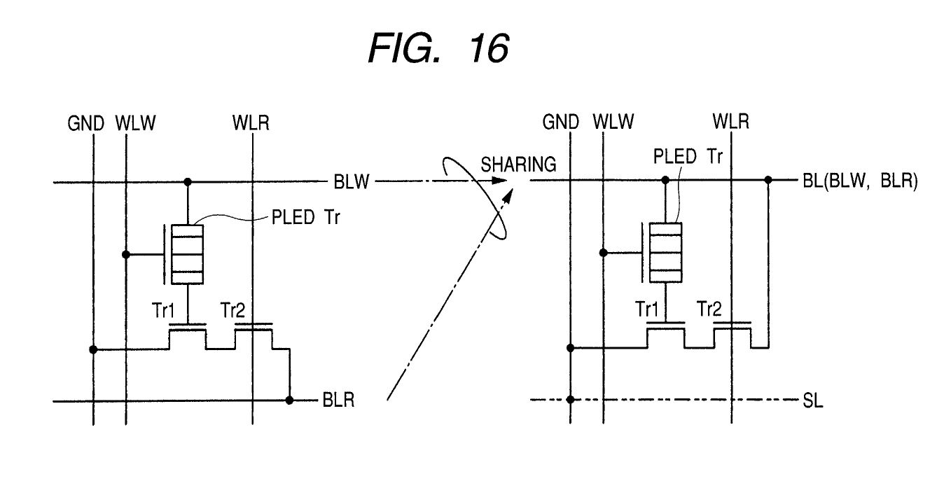

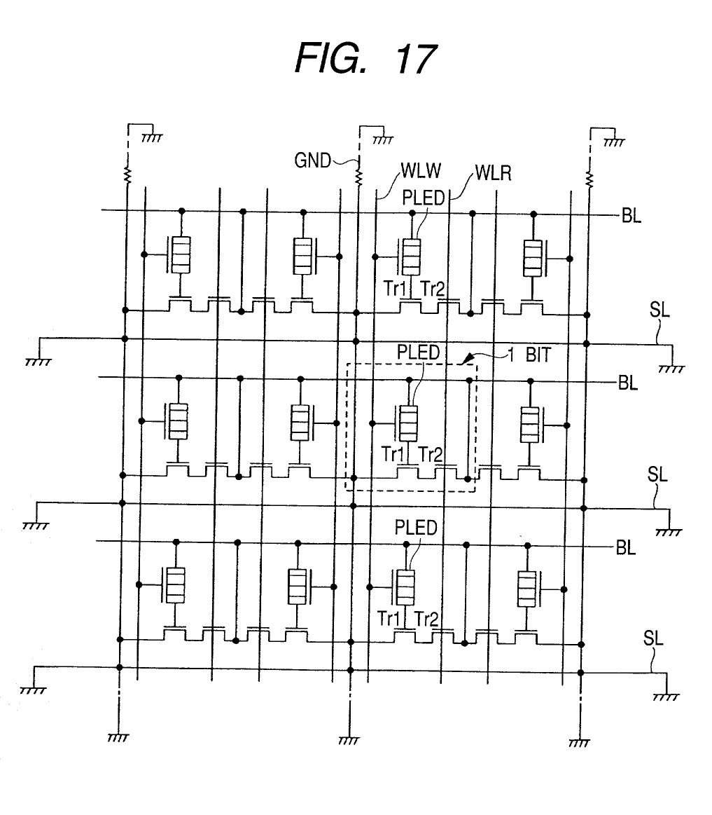

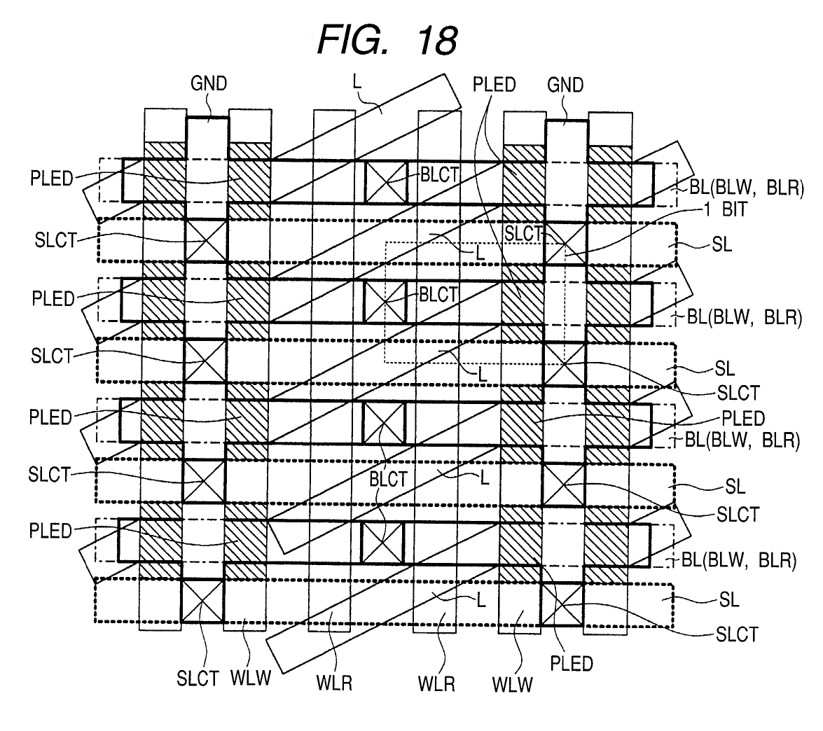

FIG. 16 is a schematic circuit diagram of a memory cell of the third embodiment. FIG. 17 is a schematic circuit diagram of a memory array using the memory cell shown in FIG. 16. FIG. 18 is a plan view of a main portion showing a plane layout of the memory array shown in FIG. 17.

As shown in FIG. 16, in the third embodiment, bit lines (fifth wiring) BL have both the functions of the write bit lines BLW and read bit lines BLR in the first embodiment. As the bit lines BL, the wiring used as the write bit lines BLW in the first embodiment can be allocated. The drain of the MISFET Tr2 electrically connected with the read bit lines BLR in the first embodiment are electrically connected with the bit lines BL in the third embodiment.

On the other hand, the wirings used as the read bit lines BLR in the first embodiment can be used as shunt lines SL in the third embodiment. The shunt lines SL are electrically connected with the source power lines GND and have the same function as the shunt lines SL (see FIG. 3) in the first embodiment. In the memory array of the third embodiment, all the wirings used as the read bit lines BLR in the first embodiment do not need to be used as the shunt lines and a proper number of lines may be used as signal lines or power lines, as required.

In the third embodiment, the areas DCA (see FIGS. 3 and 6) provided to form dummy cells in the first embodiment are not provided. Therefore, an area increase of the memory array can be prevented more effectively than the memory array of the first embodiment.

According to the memory array of the second embodiment, like the memory array of the first embodiment, the potential of the source power lines GND can be expelled to ground potential by the shunt lines SL. Thereby, noise from the source power lines GND can be reduced. Also, since a decrease in a source-to-drain voltage of MISFET Tr1 due to the noise developing in the source power lines GND can be suppressed, deterioration in a source-to-drain current of MISFET Tr1 can also be suppressed. That is, since a delay of a read time of the central bit (not shown in the third embodiment) of the word line WLR can be reduced, a difference between a read speed of the central bit of the word line WLR and a read speed of a bit near to the word driver (not shown in the third embodiment) can be reduced. As a result, since the operation timing of sense amplifiers of the memory array of the third embodiment can be sped up, a read speed of the memory array of the third embodiment can be increased like the memory array of the first embodiment.

Hitherto, the invention made by the inventor et al. has been described in detail based on the embodiments of the invention. It goes without saying that the present invention is not limited to the foregoing embodiments and may be modified in various ways without departing from the sprit and scope of the present invention.

For example, in the foregoing embodiments, in a subarray of 512 by 256 word bits, shunt lines grounded at both ends thereof and electrically connected with a source power line are disposed one every 16 bits. However, the number of lines to be disposed may be changed as required. For example, in the case where emphasis is laid on a speedup in reading a memory array, the number of lines to be disposed may be increased, while, in the case where emphasis is laid on an area reduction in the memory array, the number of lines to be disposed may be decreased.

In the first embodiment, in areas where dummy cells are formed, read bit lines are allocated as shunt lines grounded at both ends thereof and electrically connected with a source power line. However, write bit lines may be allocated as the shunt lines.

The foregoing description has been made on the case where the invention made by the inventor et al. is applied to a memory array of PLED memory, which is an application field of the invention. However, the present invention, without being limited to it, can also apply to a semiconductor integrated circuit device having memory circuits such as MRAM (Magnetic Random Access Memory).

Typical inventions of those disclosed by the present patent application provide the following effects.

(1) In a memory array comprising memory cells each having a PLED transistor (first transistor) and MISFET (second transistor), since shunt lines (fourth wiring) grounded at both ends thereof and electrically connected with MISFET source power lines (third wiring) are provided to expel noise developing in the source power lines, a read speed of the memory array can be increased.

(2) In a memory array comprising memory cells each having a PLED transistor (first transistor) and MISFET (second transistor), since areas for forming shunt lines (third wiring) grounded at both ends thereof and electrically connected with MISFET source power lines are not provided and bit lines for reading memory cells of one bit regarded as dummy cells are used as shunt lines (fourth wiring), an area increase in the memory array can be prevented.

What is claimed is:

1. A semiconductor integrated circuit device having a memory array which comprises memory cells each including a first transistor and a second transistor having a first electrode, a second electrode, and a third electrode, and includes a first area and a second area, wherein:
(a) the first electrode of the first transistor is electrically connected with a second wiring;
(b) the second electrode of the first transistor is electrically connected with a first wiring;
(c) the third electrode of the first transistor is electrically connected with the first electrode of the second transistor;
(d) the second electrode of the second transistor is electrically connected with a third wiring connected to power supply voltage at ends thereof;
(e) in the first area, the third electrode of the second transistor is electrically connected with a fourth wiring;
(f) in the second area, the third electrode of the second transistor is electrically connected with a seventh wiring connected to power supply voltage;
(g) in the second area, the seventh wiring is electrically connected with the third wiring; and
(h) the second area is disposed at a predetermined interval in the memory array.

2. The semiconductor integrated circuit device according to claim 1, wherein the memory cells have gains.

3. The semiconductor integrated circuit device according to claim 1, wherein the power supply voltage is a ground level.

4. The semiconductor integrated circuit device according to claim 1, wherein the third wiring is constituted of a first semiconductor area of a first conductive type.

5. The semiconductor integrated circuit device according to claim 1, wherein the sheet resistance of the third wiring is higher than the sheet resistance of the seventh wiring.

6. The semiconductor integrated circuit device according to claim 1, wherein the first wiring is used to write information, the second wiring is used to select memory cells, and the fourth wiring is used to read information.

7. A semiconductor integrated circuit device having a memory array which comprises memory cells each including a first transistor, a second transistor, and a third transistor having a first electrode, a second electrode, and a third electrode, and includes a first area and a second area, wherein:
(a) the first electrode of the first transistor is electrically connected with a second wiring;
(b) the second electrode of the first transistor is electrically connected with a first wiring;
(c) the third electrode of the first transistor is electrically connected with the first electrode of the second transistor;
(d) the second electrode of the second transistor is electrically connected with a third wiring connected to power supply voltage at ends thereof;
(e) in the first area, the third electrode of the second transistor is electrically connected with a fourth wiring through the third transistor;
(f) in the second area, the third electrode of the second transistor is electrically connected with a seventh wiring connected to power supply voltage through the third transistor;
(g) in the second area, the seventh wiring is electrically connected with the third wiring; and
(h) the second area is disposed at a predetermined interval in the memory array.

8. The semiconductor integrated circuit device according to claim 7, wherein the memory cells have gains.

9. The semiconductor integrated circuit device according to claim 7, wherein the power supply voltage is a ground level.

10. The semiconductor integrated circuit device according to claim 7, wherein the third wiring is constituted of a first semiconductor area of a first conductive type.

11. The semiconductor integrated circuit device according to claim 7, wherein the sheet resistance of the third wiring is higher than the sheet resistance of the seventh wiring.

12. The semiconductor integrated circuit device according to claim 7, wherein the first wiring is used to write information, the second wiring is used to select memory cells, and the fourth wiring is used to read information.

13. A semiconductor integrated circuit device having a memory array which comprises memory cells each including a first transistor, a second transistor, and a third transistor having a first electrode, a second electrode, and a third electrode, wherein:
(a) the first electrode of the first transistor is electrically connected with a second wiring;
(b) the second electrode of the first transistor is electrically connected with a fifth wiring;
(c) the third electrode of the first transistor is electrically connected with a first electrode of the second transistor;
(d) the second electrode of the second transistor is electrically connected with a third wiring connected to power supply voltage at ends thereof;
(e) the third electrode of the second transistor is electrically connected with a fifth wiring through the third transistor; and
(f) the third wiring is electrically connected with a seventh wiring connected to power supply voltage.

14. The semiconductor integrated circuit device according to claim 13, wherein the memory cells have gains.

15. The semiconductor integrated circuit device according to claim 13, wherein the power supply voltage is a ground level.

16. The semiconductor integrated circuit device according to claim 13, wherein the third wiring is constituted of a first semiconductor area of a first conductive type.

17. The semiconductor integrated circuit device according to claim 13, wherein the sheet resistance of the third wiring is higher than the sheet resistance of the seventh wiring.

18. The semiconductor integrated circuit device according to claim 13, wherein the second wiring is used to select memory cells and the fifth wiring is used to write and read information.

19. A semiconductor integrated circuit device having a memory array which comprises memory cells each including a first transistor and a second transistor having a first electrode, a second electrode, and a third electrode, and a capacitor, and includes a first area and a second area, wherein:
(a) the first electrode of the first transistor is electrically connected with a sixth wiring;
(b) the second electrode of the first transistor is electrically connected with a first wiring;
(c) the third electrode of the first transistor is electrically connected with the first electrode of the second transistor and the capacitor;
(d) the second electrode of the second transistor is electrically connected with a third wiring connected to power supply voltage at ends thereof;
(e) in the first area, the third electrode of the second transistor is electrically connected with a fourth wiring;
(f) in the second area, the third electrode of the second transistor is electrically connected with a seventh wiring connected to power supply voltage;
(g) in the second area, the seventh wiring is electrically connected with the third wiring;
(h) the second area is disposed at a predetermined interval in the memory array; and
(i) the capacitor is electrically connected with the sixth wiring.

20. The semiconductor integrated circuit device according to claim 19, wherein the memory cells have gains.

21. The semiconductor integrated circuit device according to claim 19, wherein the power supply voltage is a ground level.

22. The semiconductor integrated circuit device according to claim 19, wherein the third wiring is constituted of a first semiconductor area of a first conductive type.

23. The semiconductor integrated circuit device according to claim 19, wherein the sheet resistance of the third wiring is higher than the sheet resistance of the seventh wiring.

24. The semiconductor integrated circuit device according to claim 19, wherein the first wiring is used write information, the fourth wiring is used to read information, and the sixth wiring is used to select memory cells.

25. A semiconductor integrated circuit device having a memory array which comprises plural memory cells each including a transistor electrically connected to power supply voltage and includes a first area and a second area, wherein:
(a) the adjacent memory cells are electrically connected to power supply voltage by a third wiring;
(b) memory cells in the first area are electrically connected to a fourth wiring;
(c) memory cells in the second area are electrically connected with a seventh wiring formed by the same conductive layer as the fourth wiring; and
(d) the seventh wiring is electrically connected with the third wiring.

26. The semiconductor integrated circuit device according to claim 25, wherein the memory cells have gains.

27. The semiconductor integrated circuit device according to claim 25, wherein the third wiring is constituted of a first semiconductor area of a first conductive type.

28. The semiconductor integrated circuit device according to claim 25, wherein the sheet resistance of the seventh wiring is lower than the sheet resistance of the third wiring.

29. The semiconductor integrated circuit device according to claim 25, wherein the third wiring is orthogonal to the fourth wiring and the seventh wiring.

30. The semiconductor integrated circuit device according to claim 25, wherein the power supply voltage is a ground level.
